(19) United States
(12) Patent Application Publication
(10) Pub. No.: US 2025/0275434 A1
(43) Pub. Date: Aug. 28, 2025

(54) Display Apparatus

(71) Applicant: LG Display Co., Ltd., Seoul (KR)

(72) Inventor: Jae Hyun Ryu, Paju-si (KR)

(21) Appl. No.: 18/947,967

(22) Filed: Nov. 14, 2024

(30) Foreign Application Priority Data
Feb. 28, 2024 (KR) 10-2024-0029158

(51) Int. Cl. H10K 59/80; H10K 59/122; H10K 59/131; H10K 59/40; H10K 59/88

(52) U.S. Cl. CPC H10K 59/8731; H10K 59/122; H10K 59/131; H10K 59/40; H10K 59/88

(57) ABSTRACT

A display apparatus is provided. The display apparatus includes a light-emitting device and an encapsulation structure. The light-emitting device and the encapsulation structure can be on a device substrate. The encapsulation structure covering the light-emitting device can include at least one organic encapsulating layer between inorganic encapsulating layers. The organic encapsulating layer can be in a region defined by a dam. At least on organic insulating layer can be between the device substrate and the light-emitting device. The organic insulating layer can extend outside the dam. The inorganic encapsulating layers of the encapsulation structure can be stacked on an end portion of the organic insulating layer. A first pattern can be on the encapsulation structure. The first pattern can extend along the end portion of the organic insulating layer. Thus, in the display apparatus, the penetration of external moisture through a crack may be prevented by the first pattern.

### CROSS-REFERENCE TO RELATED APPLICATION

This application claims the benefit of Republic of Korea Patent Application No. 10-2024-0029158, filed on Feb. 28, 2024, which is hereby incorporated by reference as if fully set forth herein.

### FIELD OF TECHNOLOGY

The present disclosure relates to a display apparatus.

### BACKGROUND ART

In a display apparatus providing an image to a user, a crack can be formed in inorganic encapsulating layers. Thus, in the display apparatus, a light-emitting device can be deteriorated by external moisture penetrated through the crack.

### SUMMARY

Accordingly, the present disclosure is directed to a display apparatus that substantially obviates one or more problems due to limitations and disadvantages of the related art.

An object of the present disclosure is to provide a display apparatus capable of decreasing the deterioration of the light-emitting device due to the penetration of the external moisture.

Another object of the present disclosure is to provide a display apparatus capable of preventing or at least reducing the moisture penetration through the crack formed in the inorganic encapsulating layers of the encapsulation structure.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. A dam is disposed on the device substrate. The dam surrounds a display area of the device substrate. An organic encapsulating layer is disposed within an area defined by the dam. A first inorganic encapsulating layer is disposed between the device substrate and the organic encapsulating layer. The first inorganic encapsulating layer extends along a surface of the dam. A second inorganic encapsulating layer is disposed on the organic encapsulating layer. The second inorganic encapsulating layer is disposed on the first inorganic encapsulating layer outside the dam. An organic insulating layer is disposed between the device substrate and the first inorganic encapsulating layer. An end of the organic insulating layer is disposed outside the dam. A first pattern is disposed on the second inorganic encapsulating layer. The first pattern overlaps the end portion of the organic insulating layer.

In another embodiment, there is provided a display apparatus comprising a device substrate. The device substrate includes a display area and a bezel area. The bezel area is disposed outside the display area. A first organic insulating layer is disposed on the display area of the device substrate. The first organic insulating layer extends onto the bezel area of the device substrate. A first inorganic encapsulating layer is disposed on the first organic insulating layer. The first inorganic encapsulating layer extends outside the first organic insulating layer. A dam is disposed between the first organic insulating layer and the first inorganic encapsulating layer of the bezel area. An organic encapsulating layer is disposed on the first inorganic encapsulating layer of the display area. The organic encapsulating layer is surrounded by the dam. A second inorganic encapsulating layer is disposed on the organic encapsulating layer and the dam. The second inorganic encapsulating layer is in contact with the first inorganic encapsulating layer at the outside of the dam. A first pattern is disposed on the second inorganic encapsulating layer. The first pattern is disposed parallel to the dam. The first pattern overlaps an end portion of the first organic insulating layer.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to an embodiment of the present disclosure;

FIG. 3 is a view taken along I-I′ of FIG. 1 according to an embodiment of the present disclosure;

FIG. 4 is an enlarged view of K region in FIG. 1 according to an embodiment of the present disclosure;

FIG. 5 is a view taken along II-II′ of FIG. 1 according to an embodiment of the present disclosure;

FIG. 6 is a view taken along III-III′ of FIG. 4 according to an embodiment of the present disclosure; and

FIGS. 7 to 18 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

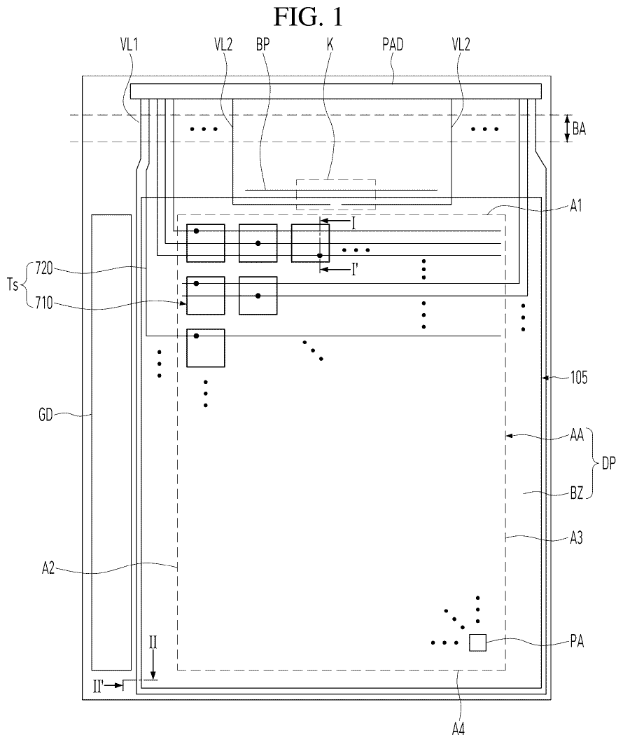

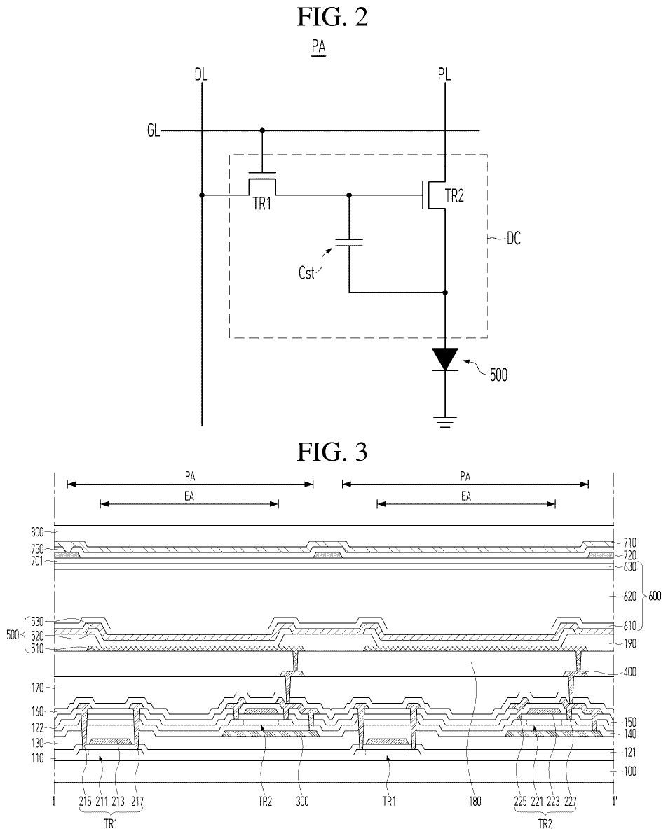

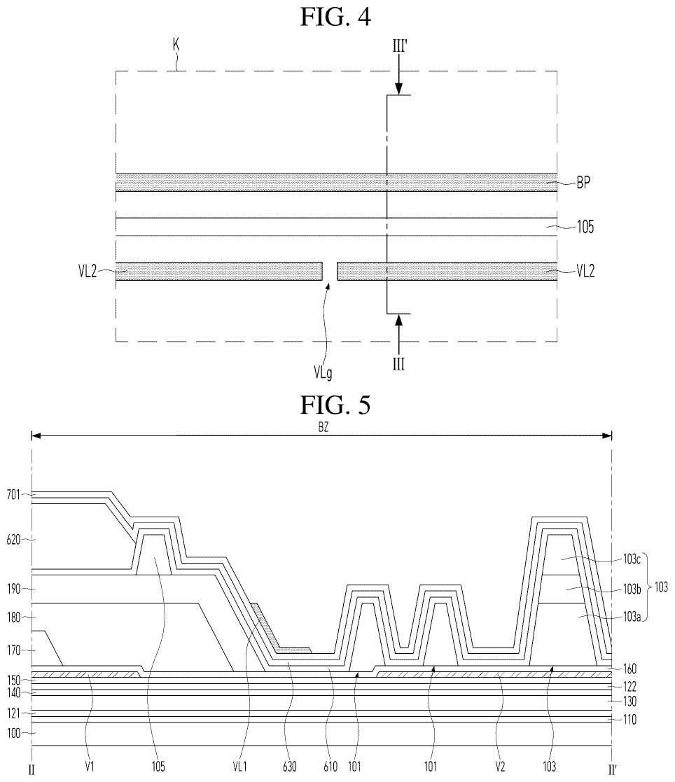

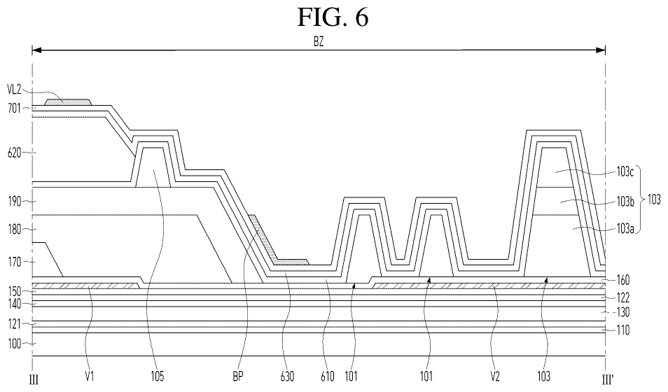

FIG. 1 is a view schematically showing a display apparatus according to an embodiment of the present disclosure. FIG. 2 is a view showing a circuit of a pixel area in the display apparatus according to an embodiment of the present disclosure. FIG. 3 is a view taken along I-I′ of FIG. 1 according to an embodiment of the present disclosure. FIG. 4 is an enlarged view of K region in FIG. 1 according to an embodiment of the present disclosure. FIG. 5 is a view taken along II-II′ of FIG. 1 according to an embodiment of the present disclosure. FIG. 6 is a view taken along III-III′ of FIG. 4 according to an embodiment of the present disclosure.

Referring to FIGS. 1 to 6, the display apparatus according to the embodiment of the present disclosure can include a display panel DP. The display panel DP can generate an image provided to a user. For example, pixel areas PA can be disposed in the display panel DP. Various signals can be provided in each pixel area PA through signal wirings GL, DL and PL. For example, the signal wirings GL, DL and PL can include gate lines GL applying a gate signal, data lines DL applying a data signal, and power lines PL supplying a positive power voltage (VDD).

Each of the pixel areas PA can realize a specific color. For example, a driving circuit DC electrically connected to a light-emitting device 500 can be disposed in each pixel area PA. The driving circuit DC of each pixel area PA can control the light-emitting device 500 of the corresponding pixel area PA according to signals applied to the signal wirings GL, DL and PL. For example, the driving circuit DC of each pixel area PA can supply a driving current corresponding to the data signal to the light-emitting device 500 of the corresponding pixel area PA according to the gate signal. The driving circuit DC of each pixel area PA can be electrically connected to one of the gate lines GL, one of the data lines DL, and one of the power lines PL. The driving current supplied to the light-emitting device 500 of each pixel area PA by the driving circuit of the corresponding pixel area PA can be maintained for one frame. For example, the driving circuit DC of each pixel area PA can include a first thin film transistor TR1, a second thin film transistor TR2, and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern 211, a first gate electrode 213, a first drain electrode 215, and a first source electrode 217. For example, the first gate electrode 213 of each pixel area PA can be electrically connected to the corresponding gate line GL, and the first drain electrode 215 of each pixel area PA can be electrically connected to the corresponding date line DL.

The first semiconductor pattern 211 can include a semiconductor material. For example, the first semiconductor pattern 211 can include lower temperature Poly-Si (LTPS). The first semiconductor pattern 211 can include a first drain region, a first channel region and a first source region. The first channel region can be disposed between the first drain region and the first source region. A resistance of the first drain region and a resistance of the first source region can be smaller than a resistance of the first channel region. For example, the first drain region and the first source region can include conductive impurities. The first channel region can be a region in which the conductive impurities are not doped.

The first gate electrode 213 can be disposed on a portion of the first semiconductor pattern 211. For example, the first gate electrode 213 can overlap the first channel region of the first semiconductor pattern 211. The first drain region and the first source region of the first semiconductor pattern 211 can be disposed outside the first gate electrode 213. The first gate electrode 213 can include a conductive material. For example, the first gate electrode 213 can include a metal, such as aluminum (Al), chrome (Cr), copper (Cu), molybdenum (Mo), titanium (Ti) and tungsten (W). The first gate electrode 213 can be spaced apart from the first semiconductor pattern 211. The first gate electrode 213 can be insulated from the first semiconductor pattern 211. For example, the first drain region of the first semiconductor pattern 211 can be electrically connected to the first source region of the first semiconductor pattern 211 according to a signal applied to the first gate electrode 213.

The first drain electrode 215 can include a conductive material. For example, the first drain electrode 215 can include a metal, such as aluminum (Al), chrome (Cr), copper (Cu), molybdenum (Mo), titanium (Ti) and tungsten (W). The first drain electrode 215 can include a different material from the first gate electrode 213. The first drain electrode 215 can be disposed on a different layer from the first gate electrode 213. The first drain electrode 215 can be electrically connected to the first drain region of the first semiconductor pattern 211. The first drain electrode 215 can be insulated from the first gate electrode 213.

The first source electrode 217 can include a conductive material. For example, the first source electrode 217 can include a metal, such as aluminum (Al), chrome (Cr), copper (Cu), molybdenum (Mo), titanium (Ti) and tungsten (W). The first source electrode 217 can include a different material from the first gate electrode 213. The first source electrode 217 can be disposed on a different layer from the first gate electrode 213. The first source electrode 217 can be disposed on a same layer as the first drain electrode 215. The first source electrode 217 can include a same material as the first drain electrode 215. The first source electrode 217 can be formed by a same process as the first drain electrode 215. For example, the first source electrode 217 can be formed simultaneously with the first drain electrode 215. The first source electrode 217 can be electrically connected to the first source region of the first semiconductor pattern 211. The first source electrode 217 can be insulated from the first gate electrode 213. The first source electrode 217 can be spaced apart from the first drain electrode 215.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can include a second semiconductor pattern 221, a second gate electrode 223, a second drain electrode 225 and a second source electrode 227. For example, the second gate electrode 223 of each pixel area PA can be electrically connected to the first source electrode 217 of the corresponding pixel area PA, and the second drain electrode 225 of each pixel area PA can be electrically connected to the corresponding power line PL.

The second semiconductor pattern 221 can include a semiconductor material. The second semiconductor pattern 221 may include a different material from the first semiconductor pattern 211. For example, the second semiconductor pattern 221 can include an oxide semiconductor, such as IGZO. The second semiconductor pattern 221 can be disposed on a different layer from the first semiconductor pattern 211.

The second semiconductor pattern 221 can include a second drain region, a second channel region, and a second source region. The second channel region can be disposed between the second drain region and the second source region. The second drain region and the second source region can have a smaller resistance than the second channel region. For example, the second drain region and the second source region can include a conductive region of an oxide semiconductor. The second channel region can be a region of an oxide semiconductor, which is not conductorized.

The second gate electrode 223 can be disposed on a portion of the second semiconductor pattern 221. For example, the second gate electrode 223 can overlap the second channel region of the second semiconductor pattern 221. The second drain region and the second source region of the second semiconductor pattern 221 can be disposed outside the second gate electrode 223. The second gate electrode 223 can include a conductive material.

For example, the second gate electrode 223 can include a metal, such as aluminum (Al), chrome (Cr), copper (Cu), molybdenum (Mo), titanium (Ti), and tungsten (W). The second gate electrode 223 can be spaced apart from the second semiconductor pattern 221. The second gate electrode 223 can be insulated from the second semiconductor pattern 221. For example, the second channel region of the second semiconductor pattern 221 can have an electrical conductivity corresponding to a voltage applied to the second gate electrode 223.

The second gate electrode 223 can include a different material from the first gate electrode 213. For example, the second gate electrode 223 can be disposed on a different layer from the first gate electrode 213.

The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. The second drain electrode 225 can be disposed on a different layer from the second gate electrode 223. The second drain electrode 225 can be electrically connected to the second drain region of the second semiconductor pattern 221. The second drain electrode 225 can be insulated from the second gate electrode 223.

The second drain electrode 225 can be disposed on a same layer as the first drain electrode 215. The second drain electrode 225 can include a same material as the first drain electrode 215. The second drain electrode 225 can be formed by a same process as the first drain electrode 215. For example, the second drain electrode 225 can be formed simultaneously with the first drain electrode 215.

The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region of the second semiconductor pattern 221. The second source electrode 227 can be insulated from the second gate electrode 223. The second source electrode 227 can be spaced apart from the second drain electrode 225.

The storage capacitor Cst of each pixel area PA can maintain a voltage applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can have a stacked structure of capacitor electrodes. For example, the storage capacitor Cst of each pixel area PA can include a first capacitor electrode electrically connected to the second gate electrode 223 of the corresponding pixel area PA, and a second capacitor electrode electrically connected to the second source electrode 227 of the corresponding pixel area PA. At least one of the capacitor electrodes of the storage capacitor Cst in each pixel area PA can be formed by using a process of forming the first thin film transistor TR1 and the second thin film transistor TR2 in the corresponding pixel area PA. Thus, in the display apparatus according to the embodiment of the present disclosure, a process of forming the driving circuit DC in each pixel area PA can be simplified.

The driving circuit DC of each pixel area PA can be supported by a device substrate 100. For example, the first thin film transistor TR1, the second thin film transistor TR2 and the storage capacitor Cst of each pixel area PA can be disposed on the device substrate 100. The device substrate 100 can include an insulating material. For example, the device substrate 100 can include glass or plastic.

A plurality of insulating layers 110, 121, 122, 130, 140, 150, 160, 170, 180 and 190 for preventing unnecessary electrical connection can be disposed on the device substrate 100. For example, a lower buffer layer 110, a lower gate insulating layer 121, an upper gate insulating layer 122, a separation insulating layer 130, an upper buffer layer 140, an upper interlayer insulating layer 150, a device passivation layer 160, a lower planarization layer 170, an upper planarization layer 180 and a bank insulating layer 190 can be disposed on the device substrate 100.

The lower buffer layer 110 can be disposed on the device substrate 100. The lower buffer layer 110 can prevent pollution due to the device substrate 100 in a process of forming the driving circuit DC of each pixel area PA. For example, an upper surface of the device substrate 100 toward the driving circuit DC of each pixel area PA can be completely covered by the lower buffer layer 110. The first thin film transistor TR1, the second thin film transistor TR2 and the storage capacitor Cst of each pixel area PA can be disposed on the lower buffer layer 110. The lower buffer layer 110 can include an insulating material. For example, the lower buffer layer 110 can be an inorganic insulating layer made of an inorganic insulating material, such as silicon oxide (SiOx) and silicon nitride (SiNx). The lower buffer layer 110 can have a multi-layer structure. For example, the lower buffer layer 110 can have a structure in which an inorganic insulating layer made of silicon oxide (SiOx) and an inorganic insulating layer made of silicon nitride (SiNx) are stacked.

The lower gate insulating layer 121 can be disposed on the lower buffer layer 110. The first gate electrode 213 of each pixel area PA can be insulated from the first semiconductor pattern 211 of the corresponding pixel area PA by the lower gate insulating layer 121. The lower gate insulating layer 121 can cover the first semiconductor pattern 211 of each pixel area PA. For example, the first semiconductor pattern 211 of each pixel area PA may be disposed between the lower buffer layer 110 and the lower gate insulating layer 121 of the corresponding pixel area PA. The first gate electrode 213 of each pixel area PA can be disposed on the lower gate insulating layer 121. The lower gate insulating layer 121 can include an insulating material. For example, the lower gate insulating layer 121 can be an inorganic insulating layer made of an inorganic insulating material, such as silicon oxide (SiOx) and silicon nitride (SiNx).

The separation insulating layer 130 can be disposed on the lower gate insulating layer 121. The first gate electrode 213 of each pixel area PA can be covered by the separation insulating layer 130. For example, the first gate electrode 213 of each pixel area PA can be disposed between the lower gate insulating layer 121 and the separation insulating layer 130 of the corresponding pixel area PA. The separation insulating layer 130 can include an insulating material. For example, the separation insulating layer 130 can be an inorganic insulating layer made of an inorganic insulating material. The separation insulating layer 130 can have a different thickness from the lower gate insulating layer 121. For example, a thickness of the separation insulating layer 130 may be greater than a thickness of the lower gate insulating layer 121.

The upper buffer layer 140 can be disposed on the separation insulating layer 130. The upper gate insulating layer 122 can be disposed on the upper buffer layer 140. The upper buffer layer 140 and the upper gate insulating layer 122 can include an insulating material. For example, the upper buffer layer 140 and the upper gate insulating layer 122 can be an inorganic insulating layer made of an inorganic insulating material, such as silicon oxide (SiOx) and silicon nitride (SiNx). The upper gate insulating layer 122 can include a different material from the upper buffer layer 140.

The upper gate insulating layer 122 can insulate the second gate electrode 223 of each pixel area PA from the second semiconductor pattern 221 of the corresponding pixel area PA. The second semiconductor pattern 221 of each pixel area PA can be covered by the upper gate insulating layer 122. For example, the second semiconductor pattern 221 of each pixel area PA can be disposed between the upper buffer layer 140 and the upper gate insulating layer 122 of the corresponding pixel area PA. The second gate electrode 223 of each pixel area PA can be disposed on the upper gate insulating layer 122.

A light-blocking pattern 300 can be disposed between the separation insulating layer 130 and the upper buffer layer 140 of each pixel area PA. The light-blocking pattern 300 of each pixel area PA can overlap the second semiconductor pattern 221 of the corresponding pixel area PA. The light-blocking pattern 300 of each pixel area PA can include a material capable of blocking light. For example, the light-blocking pattern 300 of each pixel area PA can include a metal. Thus, in the display apparatus according to the embodiment of the present disclosure, the characteristics change of the second thin film transistor TR2 in each pixel area PA due to external light through the device substrate 100 can be prevented or at least reduced. Therefore, in the display apparatus according to the embodiment of the present disclosure, the reliability of the driving circuit DC in each pixel area PA can be improved.

The upper interlayer insulating layer 150 can be disposed on the upper gate insulating layer 122. The second drain electrode 225 and the second source electrode 227 of each pixel area PA can be insulated from the second gate electrode 223 of the corresponding pixel area PA by the upper interlayer insulating layer 150. The upper interlayer insulating layer 150 can cover the second gate electrode 223 of each pixel area PA. For example, the second gate 223 of each pixel area PA can be disposed between the upper gate insulating layer 122 and the upper interlayer insulating layer 150 of the corresponding pixel area PA. The upper interlayer insulating layer 150 can include an insulating material. For example, the upper interlayer insulating layer 150 can be an inorganic insulating layer made of an inorganic insulating material. The second drain electrode 225 and the second source electrode 227 of each pixel area PA can be disposed on the upper interlayer insulating layer 150. For example, the second drain electrode 225 of each pixel area PA can be in direct contact with the second drain region of the corresponding pixel area PA by penetrating the upper interlayer insulating layer 150, and the second source electrode 227 of each pixel area PA can be in direct contact with the second source region of the corresponding pixel area PA by penetrating the upper interlayer insulating layer 150.

The first drain electrode 215 and the first source electrode 217 of each pixel area PA can be disposed on the upper interlayer insulating layer 150. For example, the first drain electrode 215 and the first source electrode 217 of each pixel area PA can be insulated from the first gate electrode 213 of the corresponding pixel area PA by the separation insulating layer 130, the upper buffer layer 140, the upper gate insulating layer 122 and the upper interlayer insulating layer 150. The first drain electrode 215 of each pixel area PA can be in direct contact with the first drain region of the corresponding pixel area PA by penetrating the separation insulating layer 130, the upper buffer layer 140, the upper gate insulating layer 122 and the upper interlayer insulating layer 150. The first source electrode 217 of each pixel area PA can be in direct contact with the first source region of the corresponding pixel area PA by penetrating the separation insulating layer 130, the upper buffer layer 140, the upper gate insulating layer 122 and the upper interlayer insulating layer 150.

The device passivation layer 160 can be disposed on the upper interlayer insulating layer 150. The device passivation layer 160 can prevent or at least reduce damage of the driving circuit DC in each pixel area PA due to external impact and moisture. The device passivation layer 160 can extend along an upper surface of the driving circuit DC in each pixel area PA opposite to the device substrate 100. For example, the first drain electrode 215, the first source electrode 217, the second drain electrode 225, and the second source electrode 227 of each pixel area PA can be covered by the device passivation layer 160. The device passivation layer 160 can include an insulating material. For example, the device passivation layer 160 can be an inorganic insulating layer made of an inorganic insulating material.

The lower planarization layer 170 can be disposed on the device passivation layer 160. The upper planarization layer 180 can be disposed on the lower planarization layer 170. For example, the lower planarization layer 170 can be disposed between the device passivation layer 160 and the upper planarization layer 180. The lower planarization layer 170 and the upper planarization layer 180 can remove a thickness difference due to the driving circuit DC of each pixel area PA. For example, an upper surface of the upper planarization layer 180 opposite to the device substrate 100 can be a flat. The lower planarization layer 170 and the upper planarization layer 180 can include an insulating material. The lower planarization layer 170 and the upper planarization layer 180 can include a different material from the device passivation layer 160. The lower planarization layer 170 and the upper planarization layer 180 can include a material having a relatively high fluidity. For example, the lower planarization layer 170 and the upper planarization layer 180 can be an organic insulating layer made of an organic insulating material. The upper planarization layer 180 can include a same material as the lower planarization layer 170. For example, a boundary between the lower planarization layer 170 and the upper planarization layer 180 may not be recognized.

The light-emitting device 500 of each pixel area PA can be disposed on the upper planarization layer 180. The light-emitting device 500 of each pixel area PA can emit light displaying a specific color. For example, the light-emitting device 500 of each pixel area PA can include a first electrode 510, a light-emitting layer 520, and a second electrode 530, which are sequentially stacked on the upper planarization layer 180 of the corresponding pixel area PA.

The first electrode 510 can include a conductive material. The first electrode 510 can include a material having a relatively high reflectance. For example, the first electrode 510 can include a metal, such as aluminum (Al) or silver (Ag). The first electrode 510 can have a multi-layer structure. For example, the first electrode 510 can have a structure in which a reflective electrode made of a metal is disposed between transparent electrodes made of a transparent conductive material, such as ITO and IZO.

The light-emitting layer 520 can generate light having luminance corresponding to a voltage difference between the first electrode 510 and the second electrode 530. For example, the light-emitting layer 520 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting layer 520 can have a multi-layer structure. For example, the light-emitting layer 520 can include at least one of a hole injection layer (HIL), a hole transport layer (HTL), an electron transport layer (ETL) and an electron injection layer (EIL). Thus, in the display apparatus according to the embodiment of the present disclosure, efficiency of the light-emitting layer 520 can be improved.

The second electrode 530 can include a conductive material. The second electrode 530 can include a different material from the first electrode 510. A transmittance of the second electrode 530 can be greater than a transmittance of the first electrode 510. For example, the second electrode 530 can be a transparent electrode made of a transparent conductive material, such as ITO and IZO. Thus, in the display apparatus according to the embodiment of the present disclosure, the light generated by the light-emitting layer 520 can be emitted outside through the second electrode 530. The second electrode 530 can have a lower work-function than the first electrode 510. For example, the first electrode 510 can function as anode electrode, and the second electrode 530 can function as cathode electrode.

The bank insulating layer 190 can be disposed on the upper planarization layer 180. The first electrode 510 of each pixel area PA can be insulated from the first electrode 510 of adjacent pixel area PA by the bank insulating layer 190. For example, an edge of the first electrode 510 in each pixel area PA can be covered by the bank insulating layer 190. The first electrode 510 of each pixel area PA can be partially exposed by the bank insulating layer 190. For example, the bank insulating layer 190 can define an emission area EA in each pixel area PA. The light-emitting layer 520 and the second electrode 530 of each pixel area PA can be stacked on the first electrode 510 overlapping with the emission area EA defined in the corresponding pixel area PA by the bank insulating layer 190. For example, the light-emitting layer 520 of each pixel area PA can be in direct contact with the first electrode 510 and the second electrode 530 in the emission area EA of the corresponding pixel area PA. The bank insulating layer 190 can include an insulating material. For example, the bank insulating layer 190 can be an organic insulating layer made of an organic insulating material. The bank insulating layer 190 can include a different material from the upper planarization layer 180.

The first electrode 510 of each pixel area PA can be electrically connected to the driving circuit DC of the corresponding pixel area PA. For example, the first electrode 510 of each pixel area PA can be in direct contact with the second source electrode 227 of the corresponding pixel area PA by penetrating the device passivation layer 160, the lower planarization layer 170 and the upper planarization layer 180. A region where the first electrode 510 of each pixel area PA is electrically connected to the second source electrode 227 of the corresponding pixel area PA can overlap the bank insulating layer 190. Thus, in the display apparatus according to the embodiment of the present disclosure, the change in the position of the first electrode 510 in the emission area EA of each pixel area PA may be minimized. For example, a portion of the first electrode 510 in the emission area EA of each pixel area PA can be in direct contact with the upper surface of the upper planarization layer 180. Therefore, in the display apparatus according to the embodiment of the present disclosure, the luminance deviation depending on the generation location of light emitted from the emission area EA of each pixel area PA can be prevented.

Intermediate electrodes 400 electrically connecting the light-emitting device 500 of each pixel area PA to the driving circuit DC of the corresponding pixel area PA can be disposed between the lower planarization layer 170 and the upper planarization layer 180. The intermediate electrodes 400 can include a conductive material. For example, the intermediate electrode 400 can include a metal, such as aluminum (Al), chrome (Cr), copper (Cu), molybdenum (Mo), titanium (Ti) and tungsten (W). Each of the intermediate electrodes 400 can be in direct contact with the second source electrode 227 and the first electrode 510 of one of the pixel areas PA. For example, the first electrode 510 of each pixel area PA can be in direct contact with one of the intermediate electrodes by penetrating the upper planarization layer 180, and each of the intermediate electrodes 400 can be in direct contact with the second source electrode 227 of one of the pixel areas PA by penetrating the lower planarization layer 170. Thus, in the display apparatus according to the embodiment of the present disclosure, the first electrode 510 of each pixel area PA can be stably connected to the second source electrode 227 of the corresponding pixel area PA. Therefore, in the display apparatus according to the embodiment of the present disclosure, the reliability of the electric connection between the driving circuit DC and the light-emitting device 500 in each pixel area PA may be improved.

The light emitted from the light-emitting device 500 of each pixel area PA can display a different color from the light emitted from the light-emitting device 500 of adjacent pixel area PA. For example, the light-emitting layer 520 of each pixel area PA can be spaced apart from the light-emitting layer 520 of adjacent pixel area PA on the bank insulating layer 190. The light-emitting layer 520 of each pixel area PA can include an end portion disposed on the bank insulating layer 190. The light-emitting layer 520 of each pixel area PA can include a different material from the light-emitting layer 520 of adjacent pixel area PA. For example, the light-emitting layer 520 of each pixel area PA can have a stacked structure different from the light-emitting layer 520 of adjacent pixel area PA.

A voltage applied to the second electrode 530 of each pixel area PA can be a same as a voltage applied to the second electrode 530 of adjacent pixel area PA. A voltage applied to the second electrode 530 of each pixel area PA can be different from a voltage supplied by the power lines PL. For example, a negative power voltage (VSS) can be applied to the second electrode 530 of each pixel area PA. The second electrode 530 of each pixel area PA can be electrically connected to the second electrode 530 of adjacent pixel area PA. The second electrode 530 of each pixel area PA can include a same material as the second electrode 530 of adjacent pixel area PA. The second electrode 530 of each pixel area PA can be formed by a same process as the second electrode 530 of adjacent pixel area PA. For example, the second electrode 530 of each pixel area PA can be formed simultaneously with the second electrode 530 of adjacent pixel area PA. The second electrode 530 of each pixel area PA can be in direct contact with the second electrode 530 of adjacent pixel area PA on the bank insulating layer 190. Thus, in the display apparatus according to the embodiment of the present disclosure, a process of forming the second electrode 530 in each pixel area PA can be simplified. And, in the display apparatus according to the embodiment of the present disclosure, the luminance of the light generated by the light-emitting layer 520 of each pixel area PA can be adjusted by the data signal applied to the driving circuit DC of the corresponding pixel area PA.

An encapsulation structure 600 can be disposed on the light-emitting device 500 of each pixel area PA. The encapsulation structure 600 can prevent or at least reduce damage of the light-emitting devices 500 due to the external impact and moisture. The encapsulation structure can include an insulating material. The encapsulation structure 600 can have a multi-layer structure. For example, the encapsulation structure 600 can have a stacked structure of an inorganic encapsulating layer 610 and 630 made of an inorganic insulating material, and an organic encapsulating layer 620 made of an organic insulating material. The organic encapsulating layer 620 can be disposed between the inorganic encapsulating layers 610 and 630. For example, the encapsulation structure 600 can include a first inorganic encapsulating layer 610, an organic encapsulating layer 620, and a second inorganic encapsulating layer 630 which are sequentially stacked. The second inorganic encapsulating layer 630 can include a different material from the first inorganic encapsulating layer 610. Thus, in the display apparatus according to the embodiment of the present disclosure, the damage of the light-emitting devices 500 due to the external moisture and impact can be effectively prevented or at least reduced.

A thickness difference due to the light-emitting device 500 of each pixel area PA can be removed by the organic encapsulating layer 620. For example, an upper surface of the encapsulation structure 600 opposite to the device substrate 100 can be flat. A thickness of the organic encapsulating layer 620 can be larger than a thickness of the first inorganic encapsulating layer 610 and a thickness of the second inorganic encapsulating layer 630.

The display panel DP can include a display area AA in which the pixel areas PA are disposed, and a bezel area BZ being disposed outside the pixel areas PA. The bezel area BZ can be disposed outside the display area AA. The bezel area BZ can have a shape extending along an edge of the display area AA. For example, the display area AA can be surrounded by the bezel area BZ.

A gate driver GD electrically connected to the gate lines GL, a data driver electrically connected to the data lines DL, a power unit electrically connected to the power lines PL, and a timing controller controlling the gate driver GD and the data driver can be disposed outside the display area AA. For example, each of the signal wirings GL, DL and PL can include a region disposed on the bezel area BZ. At least one of the gate driver GD, the data driver, the power unit (e.g., a circuit) and the timing controller can be disposed on the bezel area BZ. For example, the display apparatus according to the embodiment of the present disclosure can be a GIP (Gate In Panel) type display apparatus in which the gate driver GD is formed on the bezel area BZ of the device substrate 100.

A pad area PAD in which an external signal is applied can be disposed within the bezel area BZ. The data driver, the power unit and the timing controller disposed outside the display panel DP can supply a signal through the pad area PAD. For example, the data lines DL, the power lines PL and the gate driver GD can be electrically connected to the pad area PAD. The pad area PAD can be disposed on a side of the display area AA. The gate driver GD and the pad area PAD can be disposed on different sides of the display area AA. For example, the display area AA can include a first side A1 toward the pad area PAD, a second side A2 perpendicular to the first side A1, a third side A3 opposite to the second side A2, and a fourth side A4 opposite to the first side A1, and the gate driver GD can be disposed on the second side A2 of the display area AA.

A bending area BA can be disposed between the first side A1 of the display area AA and the pad area PAD. The bending area BA can be a curved region. For example, the display apparatus according to the embodiment of the present disclosure can be a flexible display apparatus in which the pad area PAD overlaps the display area AA by bending of the bending area BA. Thus, in the display apparatus according to the embodiment of the present disclosure, a size of the bezel area BA recognized by the user can be reduced.

At least one dam 105 can be disposed on the bezel area BZ of the device substrate 100. The dam 105 can block the flow of the organic encapsulating layer 620. For example, the dam 105 can surround the display area AA. The organic encapsulating layer 620 can be disposed in a region defined by the dam 105. For example, the organic encapsulating layer 620 can be surrounded by the dam 105. The dam 105 can be disposed close to the display area AA. For example, the dam 105 can include a region disposed between the first side A1 of the display area AA and the pad area PAD, and a region disposed between the second side A2 of the display area AA and the gate driver GD. Thus, in the display apparatus according to the embodiment of the present disclosure, the gate driver GD and/or the pad area PAD can't be covered by the organic encapsulating layer 620. Therefore, in the display apparatus according to the embodiment of the present disclosure, the movement and the damage of pads disposed in the pad area PAD and wirings in the gate driver GD due to the process of forming the organic encapsulating layer 620 can be prevented. That is, in the display apparatus according to the embodiment of the present disclosure, the decrease in the reliability due to the process of forming the organic encapsulating layer 620 can be prevented.

The dam 105 can include an insulating material. For example, the dam 105 can include an organic insulating material. The lower buffer layer 110, the lower gate insulating layer 121, the upper gate insulating layer 122, the separation insulating layer 130, the upper buffer layer 140, the upper interlayer insulating layer 150, and the device passivation layer 160, which are an inorganic insulating layer, can extend beyond the dam 105. At least one of the lower planarization layer 170, the upper planarization layer 180 and the bank insulating layer 190, which are an organic insulating layer, can include an end portion disposed outside the dam 105. For example, an end portion of the upper planarization layer 180 and an end portion of the bank insulating layer 190 can be disposed outside the dam 105. An end portion of the lower planarization layer 170 can be covered by the upper planarization layer 180. The lower buffer layer 110, the lower gate insulating layer 121, the upper gate insulating layer 122, the separation insulating layer 130, the upper buffer layer 140, the upper interlayer insulating layer 150, the device passivation layer 160, the upper planarization layer 180 and the bank insulating layer 190 can be stacked between the bezel area BZ of the device substrate 100 and the dam 105. The dam 105 can be disposed on the bank insulating layer 190 of the bezel area BZ. For example, the dam 105 can be in direct contact with an upper surface of the bank insulating layer 190 opposite to the device substrate 100.

The end portion of the upper planarization layer 180 can be covered by the bank insulating layer 190. The Water Vapor Transmission Rate (WVTR) of the bank insulating layer 190 can be lower than the WVTR of the upper planarization layer 180. Thus, in the display apparatus according to the embodiment of the present disclosure, the penetration of the external moisture through the end portion of the upper planarization layer 180 disposed outside the dam 105 can be reduced. The first inorganic encapsulating layer 610 and the second inorganic encapsulating layer 630 can be stacked on the end portion of the bank insulating layer 190. For example, the first inorganic encapsulating layer 610 can be in direct contact with the end portion of the bank insulating layer 190. The second inorganic encapsulating layer 630 can be in direct contact with the first inorganic encapsulating layer 610 at the outside of the dam 105. Therefore, in the display apparatus according to the embodiment of the present disclosure, the penetration of the external moisture through the end portion of the bank insulating layer 190 can be reduced by the first inorganic encapsulating layer 610 and the second inorganic encapsulating layer 630.

Stoppers 101 and 103 can be disposed outside the bank insulating layer 190. The flow of the lower planarization layer 170, the upper planarization layer 180 and the bank insulating layer 190, which are an organic insulating layer can be blocked by the stopper 101 and 103. The stopper 101 and 103 can include at least one intermediate stopper 101 and an outer stopper 103. The outer stopper 103 can be disposed outside the intermediate stopper 101. For example, the intermediate stopper 101 can be disposed between the dam 105 and the outer stopper 103. The end portion of the bank insulating layer 190 can be spaced apart from the intermediate stopper 101. For example, the end portion of the bank insulating layer 190 can be disposed between the dam 105 and the intermediate stopper 101.

The intermediate stopper 101 and the outer stopper 103 can be formed by using a process of forming the lower planarization layer 170, the upper planarization layer 180 and the bank insulating layer 190. For example, the intermediate stopper 101 can include a same material as the upper planarization layer 180. A thickness of the outer stopper 103 can be larger than a thickness of the intermediate stopper 101. The outer stopper 103 can have a multi-layer structure. For example, the outer stopper 103 can have a stacked structure of a first outer layer 103a including a same material as the upper planarization layer 180, a second outer layer 103b including a same material as the bank insulating layer 190, and a third outer layer 103c including a same material as the dam 105. The first outer layer 103a can be disposed on a same layer as the intermediate stopper 101. For example, the intermediate stopper 101 and the first outer layer 103a can be disposed on the device passivation layer 160 of the bezel area BZ. Thus, in the display apparatus according to the embodiment of the present disclosure, the flow of the lower planarization layer 170, the upper planarization layer 180 and the bank insulating layer 190 can be effectively controlled.

A first supply line V1 and a second supply line V2 can be disposed between the device substrate 100 and the device passivation layer 160 of the bezel area BZ. The power lines PL can be electrically connected to the first supply line V1. For example, the first supply line V1 can supply the positive power voltage (VDD). Thus, in the display apparatus according to the embodiment of the present disclosure, the positive power voltage applied to each pixel area PA can be constantly maintained. The second supply line V2 can be insulated from the first supply line V1. The second electrode 530 of each pixel area PA can be electrically connected to the second supply line V2. For example, the second supply line V2 can supply the negative power voltage (VSS). The second supply line V2 can be disposed outside the dam 105. For example, the second supply line V2 can include a region disposed between the intermediate stopper 101 and the outer stopper 103. The second electrode 530 of each pixel area PA can be electrically connected to the second supply line V2 between the intermediate stopper 101 and the outer stopper 103. Therefore, in the display apparatus according to the embodiment of the present disclosure, a process of connecting the second electrode 530 of each pixel area PA to the second supply line V2 can be simplified.

The first supply line V1 and the second supply line V2 can include a conductive material. The first supply line V1 and the second supply line V2 can include a material having a relatively low resistance. For example, the first supply line VI and the second supply line V2 can include a metal. The first supply line V1 and the second supply line V2 can be formed by using a process of forming the driving circuit DC in each pixel area PA. For example, the second supply line V2 can be disposed on a same layer as the first supply line V1. The second supply line V2 can be spaced apart from the first supply line V1. Thus, in the display apparatus according to the embodiment of the present disclosure, decrease in the process efficiency due to the process of forming the first supply line V1 and the second supply line V2 can be prevented or at least reduced.

The first supply line V1 and the second supply line V2 can be disposed on a same layer as the second drain electrode 225 of each pixel area PA. For example, the first supply line V1 and the second supply line V2 can be disposed between the upper interlayer insulating layer 150 and the device passivation layer 160 of the bezel area BZ. The second supply line V2 can include a same material as the first supply line V1. For example, the first supply line V1 and the second supply line V2 can include a same material as the second drain electrode 225 of each pixel area PA. The second supply line V2 can be formed by a same process as the first supply line V1. For example, the first supply line V1 and the second supply line V2 can be formed simultaneously with the second drain electrode 225 of each pixel area PA.

A touch sensor Ts can be disposed on the encapsulation structure 600. The touch sensor Ts can sense a touch of the user and/or a tool. The touch sensor Ts can detect a presence or an absence of a touch and the touch position of the user and/or the tool using a self-capacitance method. For example, the touch sensor Ts can include touch electrodes 710 and touch routing lines 720.

The touch electrodes 710 can overlap the display area AA of the device substrate 100. For example, the touch electrodes 710 can be disposed side by side on the encapsulation structure 600 of the display area AA. A size of each touch electrode 710 can be greater than a size of each pixel area PA. For example, each of the touch electrodes 710 can overlap a plurality of the pixel areas PA. Each of the touch electrodes 710 can overlap a plurality of the emission areas EA. The touch electrodes 710 can include a conductive material. The touch electrodes 710 can include a transparent material. For example, each of the touch electrodes 710 can be a transparent electrode made of a transparent conductive material, such as ITO and IZO. Thus, in the display apparatus according to the embodiment of the present disclosure, an area sensing the touch of the user and/or the tool can be increased. Therefore, in the display apparatus according to the embodiment of the present disclosure, the reliability for sensing the touch of the user and/or the tool can be improved.

The touch electrodes 710 can be electrically connected to the pad area PAD through the touch routing lines 720. Each of the touch electrodes 710 can be electrically connected to one of the touch routing lines 720. For example, each of the touch routing lines 720 can connect one of the touch electrodes 710 to pad area PAD. The touch routing lines 720 can be connected to the touch electrodes 710 through two sides of the display area AA, which are opposite to each other.

The touch routing lines 720 can include a conductive material. The touch routing lines 720 can include a different material from the touch electrodes 710. The touch routing lines 720 can include a material having a relative low resistance. For example, the touch routing lines 720 can include metal. The touch routing lines 720 can be disposed outside the emission area EA defined in each pixel area PA. For example, the touch routing lines 720 can overlap the bank insulating layer 190. Thus, in the display apparatus according to the embodiment of the present disclosure, the decrease in the light extraction efficiency due to the touch routing lines 720 can be prevented.

The touch routing lines 720 can be disposed on a different layer from the touch electrodes 710. For example, a touch buffer layer 701 can be disposed on the encapsulation structure 600, the touch routing lines 720 can be disposed on the touch buffer layer 701, and the touch electrodes 710 can be disposed on a touch insulating layer 750 covering the touch routing lines 720. The touch buffer layer 701 and the touch insulating layer 750 can include an insulating material. For example, the touch buffer layer 701 and the touch insulating layer 750 can include an inorganic insulating material and/or an organic insulating material. The touch insulating layer 750 can include a different material from the touch buffer layer 701. For example, the touch buffer layer 701 can be an inorganic insulating layer made of an inorganic insulating material, and the touch insulating layer 750 can be an organic insulating layer made of an organic insulating material. The touch buffer layer 701 can extend beyond the outer stopper 103 along the second inorganic encapsulating layer 630. The touch insulating layer 750 can be disposed within the display area AA. For example, the first inorganic encapsulating layer 610, the second inorganic encapsulating layer 630 and the touch buffer layer 701 can be stacked on the intermediate stopper 101 and the outer stopper 103. Thus, in the display apparatus according to the embodiment of the present disclosure, the penetration of the external moisture through the touch insulating layer 750 including an organic insulating material can be prevented or at least reduced. Therefore, in the display apparatus according to the embodiment of the present disclosure, the change in the resistance of the touch electrodes 710 due to the external moisture may be prevented.

A touch passivation layer 800 can be disposed on the touch sensor Ts. The touch passivation layer 800 can prevent or at least reduce the damage of the touch electrodes 710 due to the external impact and moisture. For example, the touch electrodes 710 can be completely covered by the touch passivation layer 800. The touch passivation layer 800 can include an insulating material. For example, the touch passivation layer 800 can include an inorganic insulating material and an organic insulating material. The touch passivation layer 800 can have a multi-layer structure. Thus, in the display apparatus according to the embodiment of the present disclosure, the damage of the touch electrodes 710 due to the external impact and moisture can be effectively prevented or at least reduced. The touch passivation layer 800 can be disposed within the display area AA. For example, the touch passivation layer 800 cannot overlap the bezel area BZ. Therefore, in the display apparatus according to the embodiment of the present disclosure, the bending stress by bending of the bending area BA can be reduced. That is, in the display apparatus according to the embodiment of the present disclosure, the crack formed in the inorganic insulating layer due to the bending stress can be reduced.

Voltage lines VL1 and VL2 can be disposed outside the touch routing lines 720. Each of the voltage lines VL1 and VL2 can supply a constant voltage. The voltage lines VL1 and VL2 can be electrically connected to the pad area PAD. For example, the voltage lines VL1 and VL2 can supply the negative power voltage (VSS). The voltage lines VL1 and VL2 can include a conductive material. The voltage lines VL1 and VL2 can include a material having a relative low resistance. For example, the voltage lines VL1 and VL2 can include a metal. The voltage lines VL1 and VL2 can be disposed on the touch buffer layer 701 of the bezel area BZ. For example, the voltage lines VL1 and VL2 can include a same material as the touch routing lines 720. The voltage lines VL1 and VL2 can be disposed on a same layer as the touch routing lines 720. The voltage lines VL1 and VL2 can be formed by a same process as the touch routing lines 720. For example, the voltage lines VL1 and VL2 can be formed simultaneously with the touch routing lines 720.

Each of the voltage lines VL1 and VL2 can extend along an edge of the display area AA. For example, the voltage lines VL1 and VL2 can include a first voltage line VL1 disposed on the second side A2, the third side A3 and the fourth side A4 of the display area AA, and a second voltage line VL2 disposed between the first side A1 of the display area AA and the pad area PAD. The first voltage line VL1 and the second voltage line VL2 can include a region disposed parallel to the dam 105. For example, the first voltage line VL1 can include a region disposed between the second side A2 of the display area AA and the gate driver GD.

The second voltage line VL2 can include a same material as the first voltage line VL1. The second voltage line VL2 can be disposed on a same layer as the first voltage line VL1. The second voltage line VL2 can be formed by a same process as the first voltage line VL1. For example, the second voltage line VL2 can be formed simultaneously with the first voltage line VL1. Thus, in the display apparatus according to the embodiment of the present disclosure, the influence of an external signal on a signal of the touch electrodes 710 and/or the touch routing lines 720 can be blocked by the voltage lines VL1 and VL2. That is, in the display apparatus according to the embodiment of the present disclosure, the distortion of a signal for sensing the touch due to the external signal can be prevented. Therefore, in the display apparatus according to the embodiment of the present disclosure, the reliability of sensing touch can be improved.

As shown in FIGS. 1, 4 and 6, the second voltage line VL2 can be spaced apart from the first voltage line VL1. The second voltage line VL2 can include a region disposed between the first side A1 of the display area AA and the dam 105. For example, a portion of the second voltage line VL2 can overlap the organic encapsulating layer 620. An opening VLg can be formed in the portion of the second voltage line VL2 overlapping with the organic encapsulating layer 620. That is, in the display apparatus according to the embodiment of the present disclosure, the portion of the second voltage line VL2 overlapping with the organic encapsulating layer 620 can be partially disconnected. Thus, in the display apparatus according to the embodiment of the present disclosure, a noise due to the external signal can be quickly emitted to pad area PAD.

A first pattern BP can be disposed between the dam 105 and the pad area PAD. The first pattern BP can be disposed on the touch buffer layer 701 of the bezel area BZ. The first pattern BP can overlap the end portion of the bank insulating layer 190. For example, the first pattern BP can extend along the end portion of the bank insulating layer 190 between the first side A1 of the display area AA and the pad area PAD. The first pattern BP can have the Water Vapor Transmission Rate (WVTR) lower than the first inorganic encapsulating layer 610, the second inorganic encapsulating layer 630 and the touch buffer layer 701. For example, the first pattern BP can include a conductive material. Thus, in the display apparatus according to the embodiment of the present disclosure, the crack formed in the first inorganic encapsulating layer 610, the second inorganic encapsulating layer 630 and/or the touch buffer layer 701 between the dam 105 and the pad area PAD due to a thickness difference by the bank insulating layer 190 and/or the bending stress can be covered by the first pattern BP. Therefore, in the display apparatus according to the embodiment of the present disclosure, the penetration of the external moisture though the crack of the first inorganic encapsulating layer 610, the second inorganic encapsulating layer 630 and/or the touch buffer layer 701, which are disposed between the dam 105 and the pad area PAD can be prevented or at least reduced by the first pattern BP. For example, the first pattern BP can function as a moisture penetration preventing layer blocking the penetration of the external moisture through the crack of the inorganic insulating layers at the beginning of the organic insulating layer, such as the upper planarization layer 180 and the bank insulating layer 190. That is, in the display apparatus according to the embodiment of the present disclosure, the deterioration of the light-emitting devices 500 due to the penetration of the external moisture can be reduced.

The opening VLg of the second voltage line VL2 can be disposed between the display area AA and the first pattern BP. Thus, in the display apparatus according to the embodiment of the present disclosure, the penetration of the external signal through the opening VLg of the second voltage line VL2 can be blocked by the first pattern BP. Therefore, in the display apparatus according to the embodiment of the present disclosure, decrease in the reliability of sensing touch can be prevented, and the noise due to the external signal can be effectively removed.

The first pattern BP can be disposed on a same layer as the second voltage line VL2. The first pattern BP can include a same material as the second voltage line VL2. The first pattern BP can be formed by a same process as the second voltage line VL2. For example, the first pattern BP can be formed simultaneously with the second voltage line VL2. For example, the first pattern BP may include a same material as at least one of the touch electrodes and the touch routing lines. Thus, in the display apparatus according to the embodiment of the present disclosure, decrease in the process efficiency due to a process of forming the first pattern BP can be prevented. Therefore, in the display apparatus according to the embodiment of the present disclosure, the deterioration of the light-emitting devices 500 due to the penetration of the external moisture can be minimized, without decrease in the process efficiency.

As shown in FIGS. 1 and 5, the first voltage line VL1 on the second side A2, the third side A3 and the fourth side A4 of the display area AA can overlap the end portion of the bank insulating layer 190. For example, the first voltage line VL1 can extend along the end portion of the bank insulating layer 190 on the second side A2, the third side A3 and the fourth side A4 of the display area AA. That is, in the display apparatus according to the embodiment of the present disclosure, a portion of the first voltage line VL1 on the second side A2, the third side A3 and the fourth side A4 of the display area AA can function as the first pattern BP. Thus, in the display apparatus according to the embodiment of the present disclosure, the penetration of the external moisture through the crack of the first inorganic encapsulating layer 610, the second inorganic encapsulating layer 630 and/or the touch buffer layer 701 on the second side A2, the third side A3 and the fourth side A4 of the display area AA can be prevented or at least reduced by the first voltage line VL1. Therefore, in the display apparatus according to the embodiment of the present disclosure, the deterioration of the light-emitting devices 500 due to the penetration of the external moisture can be effectively prevented or at least reduced.

Accordingly, the display apparatus according to the embodiment of the present disclosure can include the light-emitting devices 500 disposed on the upper planarization layer 180 of the display area AA, the bank insulating layer 190 defining the emission areas EA in which the light-emitting devices 500 are disposed, the encapsulation structure 600 covering the light-emitting devices 500 and the touch sensor Ts disposed on the encapsulation structure 600, wherein the bank insulating layer 190 covering the end portion of the upper planarization layer 180 can extend beyond the dam 105 defining a region in which the organic encapsulating layer 620 is formed, wherein the first voltage line VL1 and the first pattern BP overlapping with the end portion of the bank insulating layer 190 can be disposed on the touch buffer layer 701, and wherein the first voltage line VL1 and the first pattern BP including a same material as the touch routing lines 720 of the touch sensor Ts can extend along the end portion of the bank insulating layer 190. Thus, in the display apparatus according to the embodiment of the present disclosure, the crack of the first inorganic encapsulating layer 610, the second inorganic encapsulating layer 630 and/or the touch buffer layer 701, which are stacked on the end portion of the bank insulating layer 190 can be covered by the first voltage line VL1 or the first pattern BP. That is, in the display apparatus according to the embodiment of the present disclosure, the penetration of the external moisture through the crack formed in the first inorganic encapsulating layer 610, the second inorganic encapsulating layer 630 and/or the touch buffer layer 701 can be prevented by the first voltage line VL1 and the first pattern BP. Therefore, in the display apparatus according to the embodiment of the present disclosure, the deterioration of the light-emitting devices 500 due to the penetration of the external moisture can be reduced. And, in the display apparatus according to the embodiment of the present disclosure, the lifetime of the light-emitting devices 500 can be improved.

The display apparatus according to the embodiment of the present disclosure is described that the driving circuit DC of each pixel area PA can consist of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor capable of initializing the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the corresponding gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in configuring each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

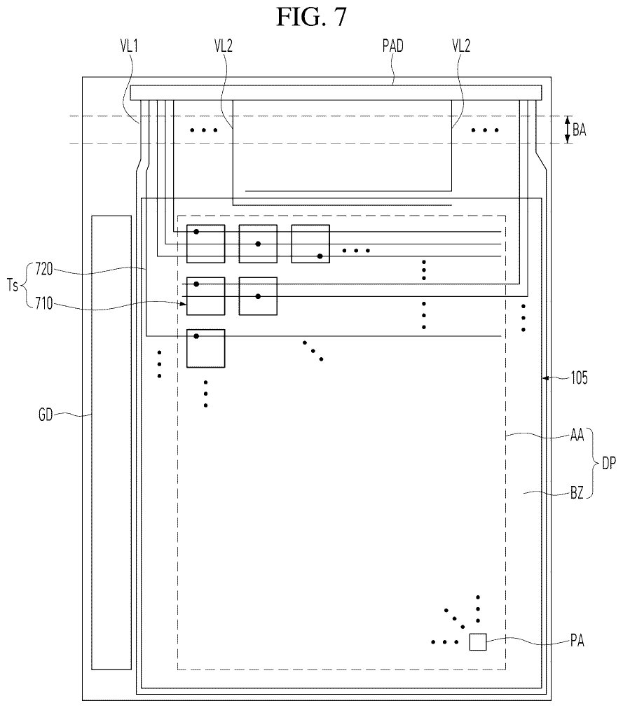

The display apparatus according to the embodiment of the present disclosure is described that the first pattern BP can be disposed between the opening VLg of the second voltage line VL2 and the pad area PAD. However, in the display apparatus according to another embodiment of the present disclosure, the first pattern BP can be omitted. For example, as shown in FIG. 7 schematically showing a plane view of the display apparatus according to another embodiment of the present disclosure, a portion of the second voltage line VL2 can be disposed between the dam 105 and the pad area PAD in the display apparatus according to the embodiment of the present disclosure. The portion of the second voltage line VL2 disposed between the dam 105 and the pad area PAD can overlap the end portion of the bank insulating layer 190. That is, in the display apparatus according to another embodiment of the present disclosure, the portion of the second voltage line VL2 can function as the first pattern. a portion of the second voltage line VL2 disposed between the first side of the display area AA and the dam 105 can extend in a direction opposite to a portion of the second voltage line VL2 disposed between the dam 105 and the pad area PAD. For example, a portion of the second voltage line VL2 disposed between the first side of the display area AA and the dam 105 can intersect between a portion of the second voltage line VL2 disposed between the dam 105 and the pad area PAD and the display area AA. Thus, in the display apparatus according to another embodiment of the present disclosure, a degree of freedom for a method preventing the penetration of the external moisture through the crack of the first inorganic encapsulating layer 610, the second inorganic encapsulating layer 630 and/or the touch buffer layer 701 disposed between the first side of the display area AA and the pad area PAD can be improved.

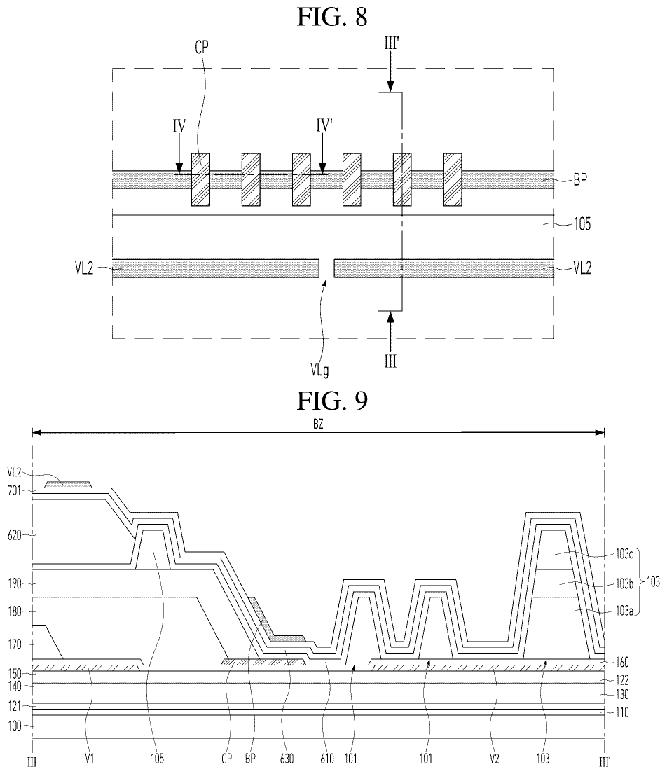

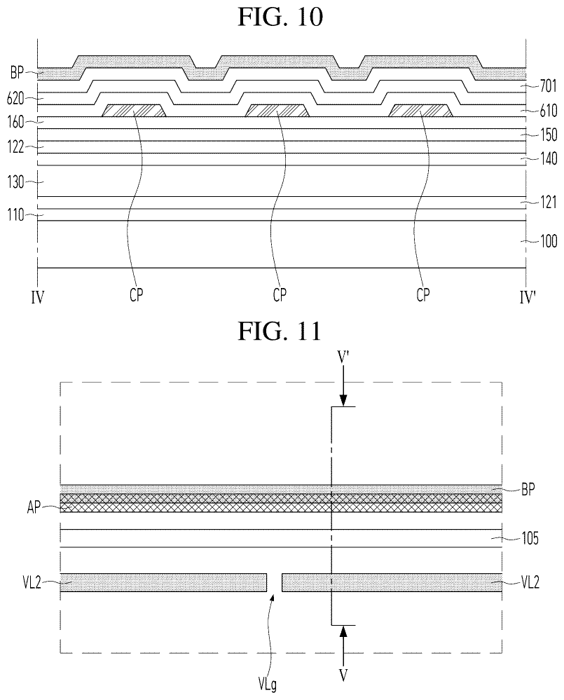

In the display apparatus according to another embodiment of the present disclosure, the propagation of the crack in a direction parallel to the first pattern BP can be prevented. FIG. 8 is an enlarged view partially showing a region around the first pattern BP in the display apparatus according to another embodiment of the present disclosure. FIG. 9 is a view taken along III-III′ of FIG. 8 according to one embodiment. FIG. 10 is a view taken along IV-IV′ of FIG. 8 according to one embodiment. Referring to FIGS. 8 to 10, the display apparatus according to another embodiment of the present disclosure can include at least one second pattern CP disposed outside the dam 105. The second pattern CP can cross the first pattern BP.

The second pattern CP can be disposed on a different layer from the first pattern BP. For example, an end portion of the second pattern CP can be disposed between the device passivation layer 160 and the first inorganic encapsulating layer 610 of the bezel area BZ, and another end portion of the second pattern CP can be disposed between the device passivation layer 160 and the bank insulating layer 190 of the bezel area BZ. Thus, in the display apparatus according to another embodiment of the present disclosure, a portion of the first inorganic encapsulating layer 610, a portion of the second inorganic encapsulating layer 630 and a portion of the touch buffer layer 701, which overlap the first pattern BP can have a concave-convex shape, as shown in FIG. 10. That is, in the display apparatus according to another embodiment of the present disclosure, a crack propagating in a direction parallel to the first pattern BP can be blocked by the concave-convex shape formed by the second pattern CP. For example, the second pattern CP can function as a crack blocking layer blocking the crack propagating along an end portion of the organic insulating layer, such as the upper planarization layer 180 and the bank insulating layer 190. Therefore, in the display apparatus according to another embodiment of the present disclosure, the penetration of the external moisture through the crack formed in the first inorganic encapsulating layer 610, the second inorganic encapsulating layer 630 and/or the touch buffer layer 701 can be effectively prevented.

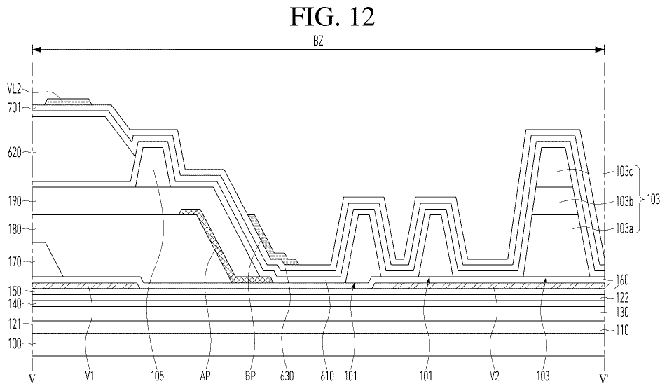

FIG. 11 is an enlarged view partially showing a region around the first pattern BP in the display apparatus according to another embodiment of the present disclosure. FIG. 12 is a view taken along V-V′ of FIG. 11 according to one embodiment of the present disclosure. Referring to FIGS. 11 and 12, the display apparatus according to another embodiment of the present disclosure can further include a dummy layer AP disposed between the upper planarization layer 180 and the bank insulating layer 190. The dummy layer AP can have a lower Water Vapor Transmittance Rate (WVTR) than the bank insulating layer 190. The dummy layer AP can be formed by using a process of forming the layer disposed between the upper planarization layer 180 and the bank insulating layer 190 of the display area AA. For example, the dummy layer AP can include a same material as the first electrode of the light-emitting layer disposed in each pixel area. The dummy layer AP can be formed by a same process as the first electrode of the light-emitting device in each pixel area. For example, the dummy layer AP can be formed simultaneously with the first electrode of the light-emitting device in each pixel area.

The end portion of the upper planarization layer 180 can be covered by the dummy layer AP. For example, the dummy layer AP can include a region disposed between the device passivation layer 160 and the bank insulating layer 190 of the bezel area BZ. An end portion of the dummy layer AP can be covered by the first inorganic encapsulating layer 610. Thus, in the display apparatus according to another embodiment of the present disclosure, the penetration of the external moisture through the end portion of the upper planarization layer 180 can be prevented by the dummy layer AP. That is, in the display apparatus according to another embodiment of the present disclosure, the external moisture penetrating through the crack of the first inorganic encapsulating layer 610, the second inorganic encapsulating layer 630 and/or the touch buffer layer 701 can be blocked by the first pattern BP and the dummy layer AP. Therefore, in the display apparatus according to another embodiment of the present disclosure, the penetration of the external moisture through the first inorganic encapsulating layer 610, the second inorganic encapsulating layer 630 and/or the touch buffer layer 701 can be effectively prevented or at least reduced.

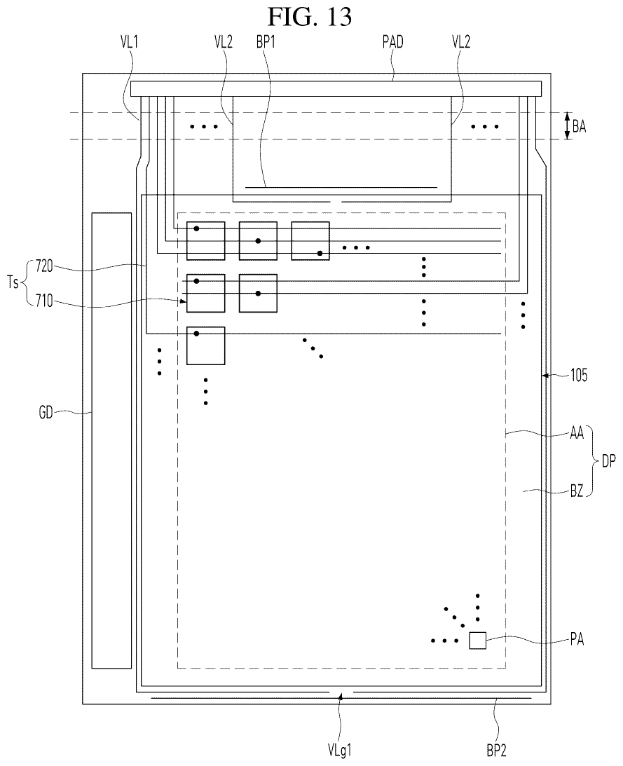

The display apparatus according to the embodiment of the present disclosure is described that the second side A2, the third side A3 and the fourth side A4 of the display area AA can be completely covered by the first voltage line VL1. However, in the display apparatus according to another embodiment of the present disclosure, a portion of the first voltage line VL1 can be disconnected. For example, referring to FIG. 13 schematically showing a plane view of the display apparatus according to another embodiment of the present disclosure in the display apparatus according to another embodiment of the present disclosure, the first voltage line VL1 can include an opening VLg1. In the display apparatus according to another embodiment of the present disclosure, the first pattern BPI can be disposed between the opening of the second voltage line VL2 and the pad area PAD, and the opening VLg1 of the first voltage line VL1 can be disposed between the second pattern BP2 and the dam 105. The second pattern BP2 can overlap the bank insulating layer. The second pattern BP2 can extend parallel to the dam 105. For example, the second pattern BP2 can extend along the end portion of the bank insulating layer on a side of the display area AA in which the opening VLg1 of the first voltage line VL1 is disposed. Thus, in the display apparatus according to another embodiment of the present disclosure, the noise generated in the first voltage line VL1 by the external signal can be quickly emitted to the pad area PAD, the penetration of the noise through the opening VLg1 of the first voltage line VL1 can be blocked by the second pattern BP2, and the penetration of the external moisture through the crack of the first inorganic encapsulating layer 610, the second inorganic encapsulating layer 630 and/or the touch buffer layer 701, which are disposed on a side of the display area AA in which the opening VLgl of the first voltage line VL1 is disposed can be effectively prevented.

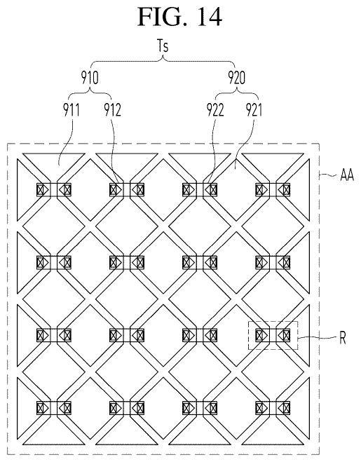

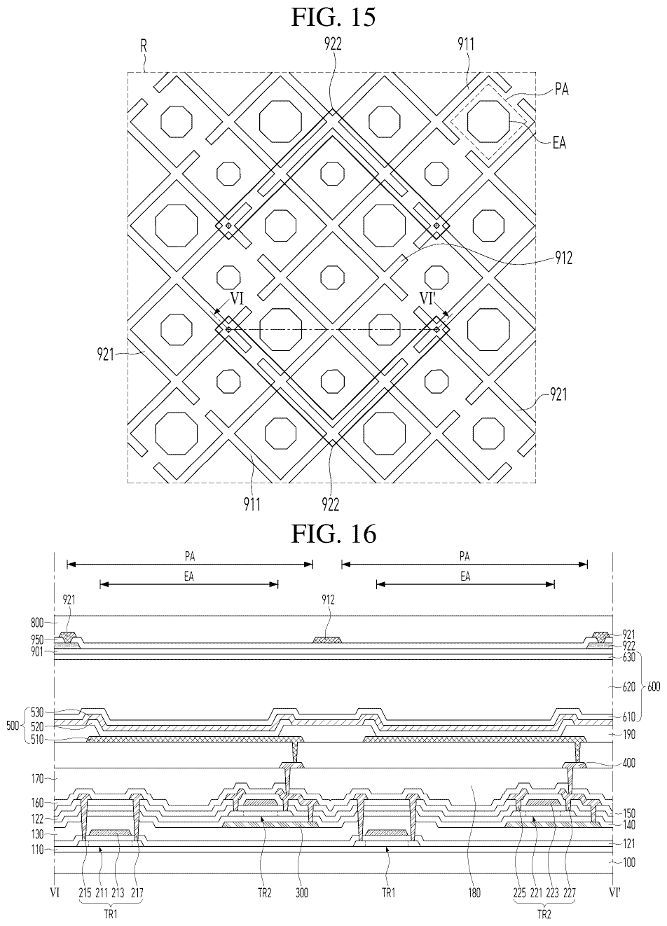

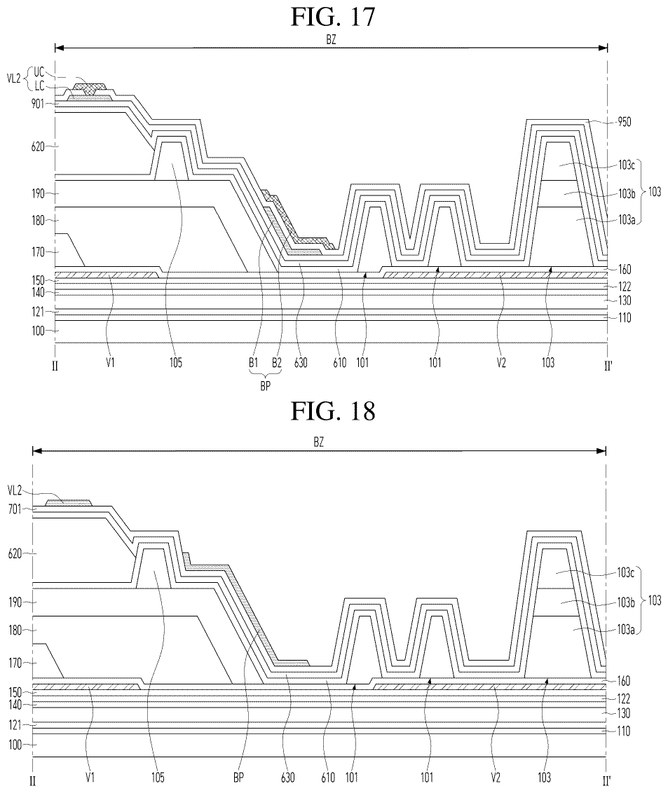

The display apparatus according to the embodiment of the present disclosure is described that the touch sensor Ts using the self-capacitance method can be disposed on the encapsulation structure 600. However, in the display apparatus according to another embodiment of the present invention, the touch sensor Ts using various methods can be used. For example, in the display apparatus according to another embodiment of the present disclosure, the touch of the user and/or the tool can be detected using the change of mutual capacitance. FIG. 14 is a view showing a plane of the touch sensor Ts in the display apparatus according to another embodiment of the present disclosure. FIG. 15 is an enlarged view of R region in FIG. 14 according to one embodiment of the present disclosure. FIG. 16 is a view taken along V1-V1′ of FIG. 15 according to one embodiment of the present disclosure. FIG. 17 is a view showing a cross-section around the first pattern BP in the display apparatus according to another embodiment of the present disclosure. Referring to FIGS. 14 to 17, in the display apparatus according to another embodiment of the present disclosure, the touch sensor Ts can include driving touch lines 910 and sensing touch lines 920.

A touch driving signal can be applied to the driving touch lines 910. For example, each of the driving touch lines 910 can include first touch electrodes 911 and first bridge electrodes 912. The first bridge electrodes 912 can electrically connect the first touch electrodes 911. For example, each of the driving touch lines 910 can include the first touch electrodes 911 connected in a direction by the first bride electrodes 912.

A touch sensing signal can be applied to the sensing touch lines 920. For example, each of the sensing touch lines 920 can include second touch electrodes 921 and second bridge electrodes 922. The second bridge electrodes 922 can electrically connect each of the second touch electrodes 921 to adjacent second touch electrode 921. The second touch electrodes 921 can be connected in a different direction from the first touch electrodes 911. For example, the connection direction of the second touch electrodes 921 by the second bridge electrodes 922 can be perpendicular to the connection direction of the first touch electrodes 911 by the first bridge electrodes 912.

The second touch electrodes 921 can be disposed on a same layer as the first touch electrodes 911. The second touch electrodes 921 can be disposed between the first touch electrodes 911. For example, the first touch electrodes 911 and the second touch electrodes 921 can be arranged to be staggered. Each of the second bridge electrodes 922 can intersect one of the first bridge electrodes 912. The first bridge electrodes 912 can be disposed on a same layer as the first touch electrodes 911. The second bridge electrodes 922 can be disposed on a different layer from the second touch electrodes 921. For example, the touch buffer layer 901 can be disposed on the second inorganic encapsulating layer 630, the second bridge electrodes 922 can be disposed on the touch buffer layer 901, and the first touch electrodes 911, the first bridge electrodes 912 and the second touch electrodes 921 can be disposed on the touch insulating layer 950 covering the second bridge electrodes 922. Each of the second touch electrodes 921 can be in direct contact with the corresponding second bridge electrode 922 by penetrating the touch insulating layer 950.

The first touch electrodes 911, the first bridge electrodes 912, the second touch electrodes 921 and the second bridge electrodes 922 can include a conductive material. The first touch electrodes 911, the first bridge electrodes 912, the second touch electrodes 921 and the second bridge electrodes 922 can include a material having a relative low resistance. For example, the first touch electrodes 911, the first bridge electrodes 912, the second touch electrodes 921, and the second bridge electrodes 922 can include a metal, such as copper (Cu), molybdenum (Mo), titanium (Ti) and Tantalum (Ta). The first touch electrodes 911, the first bridge electrodes 912, the second touch electrodes 921 and the second bridge electrodes 922 can be disposed outside the emission area EA defined in each pixel area PA. For example, the first touch electrodes 911, the first bridge electrodes 912, the second touch electrodes 921, and the second bridge electrodes 922 can overlap the bank insulating layer 190. Each of the first touch electrodes 911, the first bridge electrodes 912, the second touch electrodes 921 and the second bridge electrodes 922 can have a mesh-shaped plane. Thus, in the display apparatus according to another embodiment of the present disclosure, the decrease in the light extraction efficiency due to the first touch electrodes 911, the first bridge electrodes 912, the second touch electrodes 921 and the second bridge electrodes 922 can be prevented.

The display apparatus according to the embodiment of the present disclosure is described that the voltage lines VL1 and VL2 and the first pattern BP can have a single-layer structure. However, in the display apparatus according to another embodiment of the present invention, the voltage lines VL1 and VL2 and/or the first pattern BP can have a multi-layer structure. For example, in the display apparatus according to another embodiment of the present disclose, the second voltage line VL2 can have a stacked structure of a lower supplying layer LC and an upper supplying layer UC, and the upper supplying layer UC can be electrically connected to the lower supplying layer LC, as shown in FIGS. 16 and 17. Thus, in the display apparatus according to another embodiment of the present disclosure, a resistance of the second voltage line VL2 can be reduced.

The touch insulating layer 950 can extend along the touch buffer layer 901 beyond the outer stopper 103. The lower supplying layer LC can be disposed on a same layer as the second bridge electrodes 922. For example, the lower supplying layer LC can be disposed between the touch buffer layer 901 and the touch insulating layer 950 of the bezel area BZ. The lower supplying layer LC can include a same material as the second bridge electrodes 922. The lower supplying layer LC can be formed by a same process as the second bridge electrodes 922. For example, the lower supplying layer LC can be formed simultaneously with the second bridge electrodes 922. The upper supplying layer UC can be disposed on a same layer as the first bridge electrodes 912. For example, the upper supplying layer UC can be disposed on the touch insulating layer 950 of the bezel area BZ. The upper supplying layer UC can include a same material as the first bridge electrodes 912. The upper supplying layer UC can be formed by a same process as the first bridge electrodes 912. For example, the upper supplying layer UC can be formed simultaneously with the first bridge electrodes 912. Thus, in the display apparatus according to another embodiment of the present disclosure, the decrease in the process efficiency due to a process of forming the lower supplying layer LC and the upper supplying layer UC can be prevented.

The first pattern BP can have a stacked structure of a lower preventing layer B1 and an upper preventing layer B2. The upper preventing layer B2 can be disposed on the lower preventing layer B1. The upper preventing layer B2 can overlap the lower preventing layer B1. For example, each of the lower preventing layer B1 and the upper preventing layer B2 can include a region overlapping with the end portion of the bank insulating layer 190. Thus, in the display apparatus according to another embodiment of the present disclosure, the penetration of the external moisture through the crack of the first inorganic encapsulating layer 610, the second inorganic encapsulating layer 630 and/or the touch buffer layer 901, which are stacked on the end portion of the bank insulating layer 190 can be prevented or at least reduced by the lower preventing layer B1 and the upper preventing layer B2. Therefore, in the display apparatus according to another embodiment of the present disclosure, the penetration of the external moisture through the crack of the first inorganic encapsulating layer 610, the second inorganic encapsulating layer 630 and/or the touch buffer layer 901 can be effectively prevented or at least reduced.

The lower preventing layer B1 can be disposed on a same layer as the lower supplying layer LC. For example, the lower preventing layer B1 can be disposed between the touch buffer layer 901 and the touch insulating layer 950 of the bezel area BZ. The lower preventing layer B1 can include a same material as the lower supplying layer LC. The lower preventing layer B1 can be formed by a same process as the lower supplying layer LC. For example, the lower preventing layer B1 can be formed simultaneously with the lower supplying layer LC. The upper preventing layer B2 can be disposed on a same layer as the upper supplying layer UC. For example, the upper preventing layer B2 can be disposed on the touch insulating layer 950 of the bezel area BZ. The upper preventing layer B2 can include a same material as the upper supplying layer UC. The upper preventing layer B2 can be formed by a same process as the upper supplying layer UC. For example, the upper preventing layer B2 can be formed simultaneously with the upper supplying layer UC. For example, the upper preventing layer B2 may include a different material from the lower preventing layer B1. Thus, in the display apparatus according to another embodiment of the present disclosure, the decrease in the process efficiency due to the process of forming the lower preventing layer B1 and the upper preventing layer B2 can be prevented or at least reduced.

The upper preventing layer B2 can be insulated from the lower preventing layer B1. For example, a surface of the lower preventing layer B1 can be completely covered by the touch insulating layer 950. Thus, in the display apparatus according to another embodiment of the present disclosure, the penetration of the external moisture through a contact hole electrically connected between the lower preventing layer B1 and the upper preventing layer B2 can be prevented or at least reduced. Therefore, in the display apparatus according to another embodiment of the present disclosure, the deterioration of the light-emitting devices due to the penetration of the external moisture can be effectively prevented or at least reduced.

In the display apparatus according to another embodiment of the present disclosure, the first pattern BP can extend along an inclined side of the bank insulating layer 190. The first pattern BP can overlap at least portion of the organic insulating layer, such as the bank insulating layer 190. For example, the inorganic encapsulating layer 610 and 630 in a flat region can have a different density from the inorganic encapsulating layer 610 and 630 in an inclined region. Thus, in the display apparatus according to another embodiment of the present disclosure, the crack, such as seam generated in the inorganic encapsulating layer 610 and 630 of the inclined region can be covered by the first pattern BP. For example, in the display apparatus according to another embodiment of the present disclosure, a portion of the touch buffer layer 701 disposed between the dam 105 and the end portion of the bank insulating layer 190 can be in direct contact with the first pattern BP, as shown in FIG. 18 showing a cross-section view around the first pattern BP in the display apparatus according to another embodiment of the present disclosure. That is, in the display apparatus according to another embodiment of the present disclosure, the penetration of the external moisture through the crack generated in the inorganic insulating layers 610, 630 and 701 due to a thickness difference by the upper planarization layer 180 and the bank insulating layer 190 in the bezel area BZ and the crack generated by the deviation in the characteristics of the inorganic insulating layers 610, 630 and 701 can be effectively prevented or at least reduced. And, in the display apparatus according to another embodiment of the present disclosure, the penetration of the external moisture at the beginning of the organic insulating layer, such as the bank insulating layer 190 of the bezel area BZ can be prevented or at least reduced by the first pattern BP. Therefore, in the display apparatus according to another embodiment of the present disclosure, the deterioration of the light-emitting devices due to the penetration of the external moisture can be greatly improved.

In the result, the display apparatus according to the embodiments of the present disclosure can comprise the organic insulating layer, the first inorganic encapsulating layer, the organic encapsulating layer, the second inorganic encapsulating layer, the dam and the first pattern on the device substrate, wherein the dam surrounding the organic encapsulating layer can be disposed between the organic insulating layer and the first inorganic encapsulating layer of the bezel area, wherein the first pattern can be disposed on the second inorganic encapsulating layer contacting the first inorganic encapsulating layer outside the dam, and wherein the end portion of the organic insulating layer disposed parallel to the dam can overlap the first pattern. Thus, in the display apparatus according to the embodiments of the present disclosure, the crack formed in the first inorganic encapsulating layer and/or the second inorganic encapsulating layer can be covered by the first pattern. That is, in the display apparatus according to the embodiments of the present disclosure, the penetration of the external moisture through the crack formed in the first inorganic encapsulating layer and/or the second inorganic encapsulating layer can be blocked by the first pattern. Thereby, in the display apparatus according to the embodiments of the present disclosure, the deterioration of the light-emitting devices due to the penetration of the external moisture can be reduced. And, in the display apparatus according to the embodiments of the present disclosure, the lifetime of the light-emitting device can be increased. Further, in the display apparatus according to the embodiment of the present disclosure, low-power operation can be possible, and power consumption can be reduced.

What is claimed is:

1. A display apparatus comprising:
a dam on a device substrate, the dam surrounding a display area of the device substrate;
an organic encapsulating layer within an area defined by the dam;
a first inorganic encapsulating layer between the device substrate and the organic encapsulating layer, the first inorganic encapsulating layer extending along a surface of the dam;
a second inorganic encapsulating layer on the organic encapsulating layer, the second inorganic encapsulating layer on the first inorganic encapsulating layer outside the dam;
an organic insulating layer between the device substrate and the first inorganic encapsulating layer, the organic insulating layer including an end portion disposed outside the dam; and
a first pattern on the end portion of the organic insulating layer on the second inorganic encapsulating layer,
wherein the first pattern overlaps at least portion of the organic insulating layer.

2. The display apparatus according to claim 1, wherein the first pattern has a Water Vapor Transmission Rate (WVTR) that is lower than a WVTR of the first inorganic encapsulating layer and a WVTR the second inorganic encapsulating layer.

3. The display apparatus according to claim 1, wherein the first pattern includes a conductive material.

4. The display apparatus according to claim 3, further comprising:
a pad area outside the dam,
wherein the end portion of the organic insulating layer is between the dam and the pad area, and the first pattern is electrically connected to the pad area.

5. The display apparatus according to claim 1, further comprising:
a second pattern outside the dam, the second pattern intersecting the first pattern,
wherein the second pattern is between the device substrate and the second inorganic encapsulating layer.

6. The display apparatus according to claim 5, wherein the second pattern includes a first end between the device substrate and the first inorganic encapsulating layer and a second end between the device substrate and the organic insulating layer.

7. The display apparatus according to claim 1, further comprising:
a touch sensor on the second inorganic encapsulating layer and a pad area outside the dam,
wherein the touch sensor including touch electrodes overlapping with the display area and touch routing lines electrically connecting the touch electrodes to the pad area, and
wherein the first pattern includes a same material as at least one of the touch electrodes and the touch routing lines.

8. The display apparatus according to claim 7, wherein the touch routing lines are on a different layer from the touch electrodes.

9. The display apparatus according to claim 7, further comprising:
a touch insulating layer between the touch electrodes and the touch routing lines,
wherein the first pattern has a stacked structure of a lower preventing layer that is between the second inorganic encapsulating layer and the touch insulating layer, and an upper preventing layer that is on the touch insulating layer.

10. The display apparatus according to claim 9, wherein the upper preventing layer includes a different material from the lower preventing layer.

11. A display apparatus comprising:
a device substrate including a bezel area that is outside a display area;
a first organic insulating layer on the display area, the first organic insulating layer extending onto the bezel area;
a first inorganic encapsulating layer on the first organic insulating layer, the first inorganic encapsulating layer extending outside the first organic insulating layer;
a dam between the first organic insulating layer and the first inorganic encapsulating layer of the bezel area;
an organic encapsulating layer on the first inorganic encapsulating layer of the display area, the organic encapsulating layer surrounded by the dam;
a second inorganic encapsulating layer on the organic encapsulating layer and the dam, the second inorganic encapsulating layer contacting the first inorganic encapsulating layer on an outside of the dam; and
a first pattern on the second inorganic encapsulating layer, the first pattern disposed parallel to the dam,
wherein the first pattern overlaps an end portion of the first organic insulating layer.

12. The display apparatus according to claim 11, wherein the first pattern is in contact with the second inorganic encapsulating layer.

13. The display apparatus according to claim 11, further comprising:
a second organic insulating layer between the device substrate and the first organic insulating layer; and
a dummy layer between the first organic insulating layer and the second organic insulating layer,
wherein the dummy layer includes a region between the device substrate and the first organic insulating layer at an outside of the second organic insulating layer.

14. The display apparatus according to claim 13, further comprising:
a light-emitting device between the second organic insulating layer and the first inorganic encapsulating layer of the display area,
wherein the first organic insulating layer defines an emission area in which the light-emitting device is in the display area, and
wherein the dummy layer includes a same material as a first electrode of the light-emitting device.

15. The display apparatus according to claim 11, further comprising:
a power voltage line outside the dam, the power voltage line extending along an edge of the display area,
wherein the power voltage line includes an opening on a side of the display area and the opening of the power voltage line is between the display area and the first pattern.

16. The display apparatus according to claim 11, wherein the first pattern extends toward the dam along a surface of the second inorganic encapsulating layer,
wherein the first organic insulating layer includes an inclined side between the dam and the end portion of the first organic insulating layer and the inclined side of the first organic insulating layer overlaps the first pattern.
